(19) United States
(12) Patent Application Publication
(10) Pub. No.: US 2009/0079335 A1
(43) Pub. Date: Mar. 26, 2009

(54) LIGHT-EMITTING DEVICE, DISPLAY, AND ELECTRONIC APPARATUS

(75) Inventors: Masayuki MITSUYA, Chino-shi (JP); Koji YASUKAWA, Suwa-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/182,623

(22) Filed: Jul. 30, 2008

(30) Foreign Application Priority Data
Sep. 21, 2007 (JP) 2007-246297

(51) Int. Cl. H01J 1/63

(52) U.S. Cl. 313/504

(57) ABSTRACT

A light-emitting device includes a cathode, an anode, a first light-emitting layer that is disposed between the cathode and the anode and that emits light of a first color, a second light-emitting layer that is disposed between the first light-emitting layer and the cathode and that emits light of a second color different from the first color, and an intermediate layer that is disposed between and in contact with the first light-emitting layer and the second light-emitting layer and that functions to prevent energy transfer of excitons between the first light-emitting layer and the second light-emitting layer. The intermediate layer contains an acene-based material and an amine-based material.

### BACKGROUND

1. Technical Field

The present invention relates to light-emitting devices, displays, and electronic apparatuses.

2. Related Art

An organic electroluminescent (EL) device is a light-emitting device including at least one organic light-emitting layer between an anode and a cathode. In this type of light-emitting device, an electric field is applied between the anode and the cathode to inject electrons from the cathode into the light-emitting layer and holes from the anode into the light-emitting layer. The electrons and the holes then recombine together in the light-emitting layer to generate excitons. When the excitons return to the ground state, their energy is released in the form of light.

One such light-emitting device includes three light-emitting layers, corresponding to red (R), green (G), and blue (B), that are stacked between the anode and the cathode so that the device can emit white light (for example, see JP-A-2006-172762 (Patent Document 1)). This white lights emitting device can be used in combination with red (R), green (G), and blue (B) color filters provided in individual pixels to display a full-color image.

The light-emitting device according to Patent Document 1 further includes an intermediate layer between the light-emitting layers to prevent energy transfer of excitons between the light-emitting layers. Because the intermediate layer is bipolar, meaning that both electrons and holes can travel therethrough, it allows electrons and holes to be injected into the light-emitting layers while having a high tolerance to electrons and holes. The intermediate layer thus enables white light emission with a good balance of light emission between the light-emitting layers.

The light-emitting device according to Patent Document 1, however, has low durability because the intermediate layer is formed only of a common hole-transporting material or electron-transporting material. In this case, the bipolar intermediate layer has a low tolerance to excitons generated when electrons and holes recombine together in the intermediate layer.

### SUMMARY

An advantage of some aspects of the invention is that it provides a light-emitting device with high light-emission efficiency and high durability (long lifetime), a reliable display including the light-emitting device, and a reliable electronic apparatus including the display.

A light-emitting device according to an aspect of the invention includes a cathode, an anode, a first light-emitting layer that is disposed between the cathode and the anode and that emits light of a first color, a second light-emitting layer that is disposed between the first light-emitting layer and the cathode and that emits light of a second color different from the first color, and an intermediate layer that is disposed between and in contact with the first light-emitting layer and the second light-emitting layer and that functions to prevent energy transfer of excitons between the first light-emitting layer and the second light-emitting layer. The intermediate layer contains an acene-based material and an amine-based material.

In the above light-emitting device, the intermediate layer prevents energy transfer of excitons between the first light-emitting layer and the second light-emitting layer so that both the first light-emitting layer and the second light-emitting layer can efficiently emit light. In addition, the intermediate layer allows light emission by injecting electrons and holes into the first light-emitting layer and the second light-emitting layer while having a high tolerance to electrons and holes because the amine-based material (i.e., a material having an amine backbone) has a hole-transportation capability and the acene-based material (i.e., a material having an acene backbone) has an electron-transportation capability.

In particular, the acene-based material has a high tolerance to excitons and can therefore prevent or inhibit degradation of the intermediate layer due to excitons, thus improving the durability of the light-emitting device.

In the light-emitting device according to the above aspect of the invention, the acene-based material preferably has a higher electron mobility than the amine-based material.

An acene-based material generally has a high electron-transportation capability. Hence, electrons can be smoothly conveyed from the second light-emitting layer to the first light-emitting layer through the intermediate layer.

In the light-emitting device according to the above aspect of the invention, the amine-based material preferably has a higher hole mobility than the acene-based material.

An amine-based material generally has a high hole-transportation capability. Hence, holes can be smoothly conveyed from the first light-emitting layer to the second light-emitting layer through the intermediate layer.

In the light-emitting device according to the above aspect of the invention, the acene-based material is preferably an anthracene derivative.

In this case, the acene-based material (and therefore the intermediate layer) can have a high electron-transportation capability and a high tolerance to excitons, and a uniform intermediate layer can readily be formed.

In the light-emitting device according to the above aspect of the invention, the anthracene derivative preferably has naphthyl groups at the 9- and 10-positions of an anthracene backbone.

In this case, the advantages that the acene-based material (and therefore the intermediate layer) can have a high electron-transportation capability and a high tolerance to excitons and that a uniform intermediate layer can readily be formed can more reliably be achieved.

In the light-emitting device according to the above aspect of the invention, the intermediate layer preferably has an average thickness of 1 to 100 nm.

In this case, the intermediate layer can prevent energy transfer of excitons between the first light-emitting layer and the second light-emitting layer more reliably with low drive voltage.

In the light-emitting device according to the above aspect of the invention, if the content of the acene-based material in the intermediate layer is A (percent by weight), and the content of the amine-based material in the intermediate layer is B (percent by weight), B/(A+B) is preferably 0.1 to 0.9.

In this case, the intermediate layer more reliably allows light emission by injecting electrons and holes into the first light-emitting layer and the second light-emitting layer while having a high tolerance to carriers and excitons.

The light-emitting device according to the above aspect of the invention preferably further includes a third light-emitting layer that is disposed between the first light-emitting layer and the anode or between the second light-emitting layer and the cathode and that emits light of a third color different from the first and second colors.

In this case, the light-emitting device can emit, for example, white light by combining red (R) light, green (G) light, and blue (B) light.

In the light-emitting device according to the above aspect of the invention, the first light-emitting layer is preferably a red light-emitting layer that emits red light as the light of the first color.

A red light-emitting material easily emits light because it has a relatively narrow bandgap. Hence, a good balance of light emission between the first to third light-emitting layers can be achieved if the red light-emitting layer is disposed on the anode side as the first light-emitting layer and light-emitting layers that have wider bandgaps and therefore emit light less easily are disposed on the cathode side as the second and third light-emitting layers.

In the light-emitting device according to the above aspect of the invention, preferably, the third light-emitting layer is a green light-emitting layer that is disposed between the second light-emitting layer and the cathode and that emits green light as the light of the third color, and the second light-emitting layer is a blue light-emitting layer that emits blue light as the light of the second color.

In this case, the light-emitting device can relatively easily be adapted to emit white light with a good balance between red (R) light, green (G) light, and blue (B) light.

In the light-emitting device according to the above aspect of the invention, preferably, the third light-emitting layer is a blue light-emitting layer that is disposed between the first light-emitting layer and the anode and that emits blue light as the light of the third color, and the second light-emitting layer is a green light-emitting layer that emits green light as the light of the second color.

In this case, the light-emitting device can relatively easily be adapted to emit white light with a good balance between red (R) light, green (G) light, and blue (B) light.

It is preferable that a display include the light-emitting device according to the above aspect of the invention.

In this case, a reliable display can be provided.

It is preferable that an electronic apparatus include the above display.

In this case, a reliable electronic apparatus can be provided.

### BRIEF DESCRIPTION OF THE DRAWINGS

The invention will be described with reference to the accompanying drawings, wherein like numbers reference like elements.

FIG. 1 is a longitudinal sectional view schematically showing a light-emitting device according to a first embodiment of the invention.

FIG. 2 is a longitudinal sectional view schematically showing a light-emitting device according to a second embodiment of the invention.

FIG. 3 is a longitudinal sectional view showing a display according to an embodiment of the invention.

FIG. 4 is a perspective view showing a mobile (notebook) personal computer as an example of an electronic apparatus according to an embodiment of the invention.

FIG. 5 is a perspective view showing a cellular phone (or PHS) as an example of an electronic apparatus according to another embodiment of the invention.

FIG. 6 is a perspective view showing a digital still camera as an example of an electronic apparatus according to another embodiment of the invention.

### DESCRIPTION OF EXEMPLARY EMBODIMENTS

Light-emitting devices, displays, and electronic apparatuses according to preferred embodiments of the invention will now be described with reference to the attached drawings.

### First Embodiment

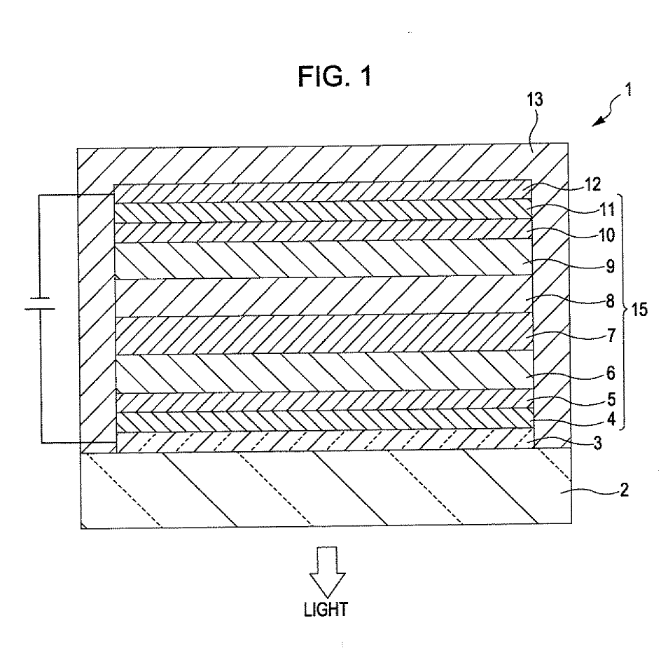

FIG. 1 is a longitudinal sectional view schematically showing a light-emitting device according to a first embodiment of the invention. For convenience of illustration, the top of FIG. 1 is referred to as the “top” of the device, whereas the bottom of FIG. 1 is referred to as the “bottom” of the device.

Referring to FIG. 1, a light-emitting device (EL device) 1 emits white light by combining red (R) light, green (G) light, and blue (B) light.

The light-emitting device 1 includes an anode 3, a hole-injecting layer 4, a hole-transporting layer 5, a red light-emitting layer (first light-emitting layer) 6, an intermediate layer 7, a blue light-emitting layer (second light-emitting layer) 8, a green light-emitting layer (third light-emitting layer) 9, an electron-transporting layer 10, an electron-injecting layer 11, and a cathode 12 that are stacked in the above order.

In other words, the light-emitting device 1 includes a laminate 15 formed between the two electrodes (the anode 3 and the cathode 12) by stacking the hole-injecting layer 4, the hole-transporting layer 5, the red light-emitting layer 6, the intermediate layer 7, the blue light-emitting layer 8, the green light-emitting layer 9, the electron-transporting layer 10, and the electron-injecting layer 11 in the above order.

The entire light-emitting device 1 is disposed on a substrate 2 and is sealed by a sealing member 13.

In the light-emitting device 1, electrons are supplied (injected) from the cathode 12 into the light-emitting layers 6, 8, and 9, whereas holes are supplied (injected) from the anode 3 into the light-emitting layers 6, 8, and 9. In the light-emitting layers 6, 8, and 9, the electrons and the holes recombine together to release energy, thereby generating excitons. When the excitons return to the ground state, their energy (fluorescence or phosphorescence) is released (emitted). The light-emitting device 1 thus emits white light.

The substrate 2 supports the anode 3. The light-emitting device 1 according to this embodiment is configured so that light exits from the substrate 2 (bottom-emission structure), and hence the substrate 2 and the anode 3 are substantially transparent (colorless transparent, colored transparent, or translucent).

Examples of the material of the substrate 2 include resin materials such as polyethylene terephthalate, polyethylene naphthalate, polypropylene, cycloolefin polymer, polyamide, polyethersulfone, poly(methyl methacrylate), polycarbonate, and polyarylate; and glass materials such as quartz glass and soda glass. These materials may be used alone or in combination of two or more.

The average thickness of the substrate 2 is preferably, but not limited to, about 0.1 to 30 mm, more preferably about 0.1 to 10 mm.

If the light-emitting device 1 is configured so that light exits from the side opposite the substrate 2 (top-emission structure), the substrate 2 may be either a transparent substrate or a nontransparent substrate.

Examples of nontransparent substrates include ceramic substrates such as alumina substrates; metal substrates, such as stainless steel substrates, coated with oxide films (insulating films); and resin substrates.

The components of the light-emitting device 1 will now be sequentially described.

Anode

The anode 3 is an electrode for injecting holes into the hole-transporting layer 5 through the hole-injecting layer 4, as described below. The anode 3 is preferably formed of a material with a high work function and good conductivity.

Examples of the material of the anode 3 include oxides such as indium tin oxide (ITO), indium zinc oxide (IZO), In₃O₃, SnO₂, antimony-containing SnO₂, and aluminum-containing ZnO; and metals such as gold, platinum, silver, copper, and alloys thereof. These materials may be used alone or in combination of two or more.

The average thickness of the anode 3 is preferably, but not limited to, about 10 to 200 nm, more preferably about 50 to 150 nm.

Cathode

The cathode 12 is an electrode for injecting electrons into the electron-transporting layer 10 through the electron-injecting layer 11, as described below. The cathode 12 is preferably formed of a material with a low work function.

Examples of the material of the cathode 12 include lithium, magnesium, calcium, strontium, lanthanum, cerium, erbium, europium, scandium, yttrium, ytterbium, silver, copper, aluminum, cesium, rubidium, and alloys thereof. These materials may be used alone or in combination of two or more (for example, in the form of a laminate of different layers).

In particular, if an alloy is used as the material of the cathode 12, the alloy used is preferably an alloy containing a stable metal element such as silver, aluminum, or copper, for example, magnesium-silver alloy, aluminum-lithium alloy, or copper-lithium alloy. The use of such an alloy as the material of the cathode 12 improves the electron-injection efficiency and stability of the cathode 12.

The average thickness of the cathode 12 is preferably, but not limited to, about 100 to 10,000 nm, more preferably about 200 to 500 nm.

The cathode 12 does not have to be transparent because the light-emitting device 1 according to this embodiment has the bottom-emission structure.

Hole-Injecting Layer

The hole-injecting layer 4 functions to improve the efficiency of hole injection from the anode 3.

Examples of the material (hole-injecting material) of the hole-injecting layer 4 include, but not limited to, copper phthalocyanine and 4,4′, 4″-tris(N,N-phenyl-3-methylphenylamino)triphenylamine (m-MTDATA).

The average thickness of the hole-injecting layer 4 is preferably, but not limited to, about 5 to 150 nm, more preferably about 10 to 100 nm.

The hole-injecting layer 4 may be omitted.

Hole-Transporting Layer

The hole-transporting layer 5 functions to transport holes injected from the anode 3 through the hole-injecting layer 4 to the red light-emitting layer 6.

Examples of the material of the hole-transporting layer 5 include various p-type polymer materials and various p-type low-molecular-weight materials. These materials may be used alone or in combination.

The average thickness of the hole-transporting layer 5 is preferably, but not limited to, about 10 to 150 nm, more preferably about 10 to 100 nm.

The hole-transporting layer 5 may be omitted.

Red Light-Emitting Layer

The red light-emitting layer (first light-emitting layer) 6 contains a red light-emitting material that emits red light (first color).

The red light-emitting material used is not particularly limited. Examples of the red light-emitting material include various red fluorescent materials and various red phosphorescent materials. These materials may be used alone or in combination of two or more.

The red fluorescent material used may be any material that emits red fluorescence. Examples of the red fluorescent material include perylene derivatives, europium complexes, benzopyran derivatives, rhodamine derivatives, benzothioxanthene derivatives, porphyrin derivatives, Nile red, 2-(1,1-dimethylethyl)-6-(2-(2,3,6,7-tetrahydro-1,1,7,7-tetramethyl-1H,5H-benzo(ij)quinolizin-9-yl)ethenyl)-4H-pyran-4H-ylidene)propanedinitrile (DCJTB), and 4-(dicyanomethylene)-2-methyl-6-(p-dimethylaminostyryl)-4H-pyran (DCM).

The red phosphorescent material used may be any material that emits red phosphorescence. Examples of the red phosphorescent material include metal complexes such as those of iridium, ruthenium, platinum, osmium, rhenium, and palladium. In these metal complexes, at least one of their ligands may have, for example, a phenylpyridine backbone, a bipyridyl backbone, or a porphyrin backbone, Specific examples include tris(1-phenylisoquinoline)iridium, bis[2-(2′-benzo[4,5-α]thienyl pyridinato-N,C3′]iridium(acetylacetonate) (btp2Ir(acac)), 2,3,7,8,12,13,17,18-octaethyl-12H,23H-porphyrin-platinum(II), bis[2-(2′-benzo[4,5-α]thienyl)pyridinato-N,C3′]iridium, and bis(2-phenylpyridine)iridium(acetylacetonate).

In addition, a host material containing the red light-emitting material as a guest material may be used as the material of the red light-emitting layer 6. The host material functions to excite the red light-emitting material by generating excitons through the recombination of electrons and holes and transferring the energy of the excitons to the red light-emitting material (Forster transfer or Dexter transfer). To use the host material, for example, it may be doped with the guest material, namely, the red light-emitting material, as a dopant.

The host material used may be any material that has the above effect on the red light-emitting material. Examples of the host material used if the red light-emitting material is a red fluorescent material include distyrylarylene derivatives, naphthacene derivatives, perylene derivatives, distyrylbenzene derivatives, distyrylamine derivatives, quinolinolato metal complexes such as tris(8-quinolinolato)aluminum (Alq₃), triarylamine derivatives such as triphenylamine tetramer, oxadiazole derivatives, silole derivatives, dicarbazole derivatives, oligothiophene derivatives, benzopyran derivatives, triazole derivatives, benzoxazole derivatives, benzothiazole derivatives, quinoline derivatives, and 4,4′-bis(2,2′-diphenylvinyl)biphenyl (DPVBi). These materials may be used alone or in combination of two or more.

Examples of the host material used if the red light-emitting material is a red phosphorescent material include carbazole derivatives such as 3-phenyl-4-(1′-naphthyl)-5-phenylcarbazole and 4,4′-N,N′-dicarbazolebiphenyl (CBP). These materials may be used alone or in combination of two or more.

If the host material is used in combination with the red light-emitting material (guest material), the content (dosage) of the red light-emitting material in the red light-emitting layer 6 is preferably 0.01% to 10% by weight, more preferably 0.1% to 5% by weight. If the content of the red light-emitting material falls within the above ranges, the light-emission efficiency can be optimized, so that the red light-emitting layer 6 can emit light with a good balance of light intensity between the red light-emitting layer 6, the blue light-emitting layer 8, and the green light-emitting layer 9.

A red light-emitting material easily traps electrons and holes and emits light because it has a relatively narrow bandgap. Hence, a good balance of light emission between the light-emitting layers 6, 8, and 9 can be achieved if the red light-emitting layer 6 is disposed on the anode 3 side and the blue light-emitting layer 8 and the green light-emitting layer 9, which emit light less easily because they have wider bandgaps, are disposed on the cathode 12 side.

Intermediate Layer

The intermediate layer 7 is disposed between and in contact with the red light-emitting layer 6 and the blue light-emitting layer 8. The intermediate layer 7 functions to block energy transfer of excitons between the red light-emitting layer 6 and the blue light-emitting layer 8. This function allows both the red light-emitting layer 6 and the blue light-emitting layer 8 to emit light efficiently.

In particular, the intermediate layer 7 contains an acene-based material and an amine-based material.

An amine-based material (i.e., a material having an amine backbone) has a hole-transportation capability, whereas an acene-based material (i.e., a material having an acene backbone) has an electron-transportation capability. The intermediate layer 7 is therefore bipolar, meaning that it has both an electron-transportation capability and a hole-transportation capability. If the intermediate layer 7 is bipolar, it can smoothly convey holes from the red light-emitting layer 6 to the blue light-emitting layer 8 and electrons from the blue light-emitting layer 8 to the red light-emitting layer 6. As a result, the electrons and the holes can efficiently be injected into the red light-emitting layer 6 and the blue light-emitting layer 8, so that they can efficiently emit light.

Because the intermediate layer 7 is bipolar, additionally, it has a high tolerance to carriers (electrons and holes). Furthermore, the acene-based material, having a high tolerance to excitons, can prevent or inhibit degradation of the intermediate layer 7 due to excitons generated when electrons and holes recombine together in the intermediate layer 7. The prevention or inhibition of degradation of the intermediate layer 7 due to excitons improves the durability of the light-emitting device 1.

The amine-based material used for the intermediate layer 7 may be any material that has an amine backbone and that provides the above effect. Of the hole-transporting materials described above, for example, those having an amine backbone may be used, and benzidine-based amine derivatives are preferred.

Among benzidine-based amine derivatives, those having two or more naphthyl groups are preferred as the amine-based material used for the intermediate layer 7. Such benzidine-based amine derivatives are exemplified by N,N′-bis(1-naphthyl)-N,N′-diphenyl-1,1′-biphenyl-4,4′-diamine (α-NPD), as represented by Chemical Formula 1 below, and N,N,N′,N′-tetranaphthyl-benzidine (TNB), as represented by Chemical Formula 2 below.

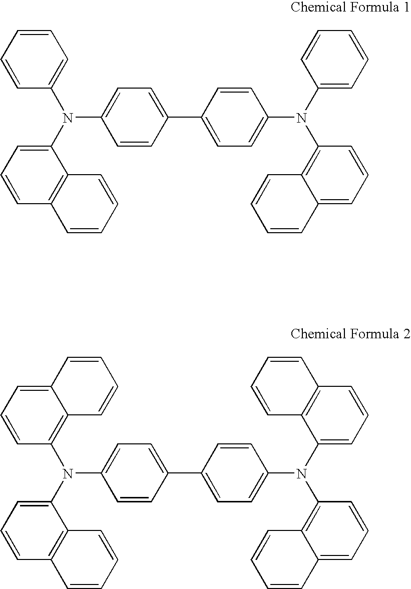

An amine-based material, which generally has a high hole-transportation capability, has a higher hole mobility than an acene-based material. Hence, holes can be smoothly conveyed from the red light-emitting layer 6 to the blue light-emitting layer 8 through the intermediate layer 7.

The content of the amine-based material in the intermediate layer 7 is preferably, but not limited to, 10% to 90% by weight, more preferably 30% to 70% by weight, and most preferably 40% to 60% by weight.

The acene-based material used for the intermediate layer 7, on the other hand, may be any material that has an acene backbone and that provides the above effect. Examples of the acene-based material include naphthalene derivatives, anthracene derivatives, tetracene derivatives, pentacene derivatives, hexacene derivatives, and heptacene derivatives. These materials may be used alone or in combination of two or more. In particular, anthracene derivatives are preferred.

Anthracene derivatives have a high electron-transportation capability, and their films can readily be formed by vapor deposition. Hence, if the acene-based material used is an anthracene derivative, the acene-based material (and therefore the intermediate layer 7) can have a high electron-transportation capability, and a uniform intermediate layer can readily be formed.

Among anthracene derivatives, those having naphthyl groups at the 9- and 10-positions of the anthracene backbone are preferred as the acene-based material used for the intermediate layer 7. In this case, the above effect can be enhanced. Such anthracene derivatives are exemplified by 9,10-di(2-naphthyl)anthracene (ADN), as represented by Chemical Formula 3 below, 2-t-butyl-9,10-di(2-naphthyl)anthracene (TBADN), as represented by Chemical Formula 4 below, and 2-methyl-9,10-di(2-naphthyl)anthracene (MADN), as represented by Chemical Formula 5 below.

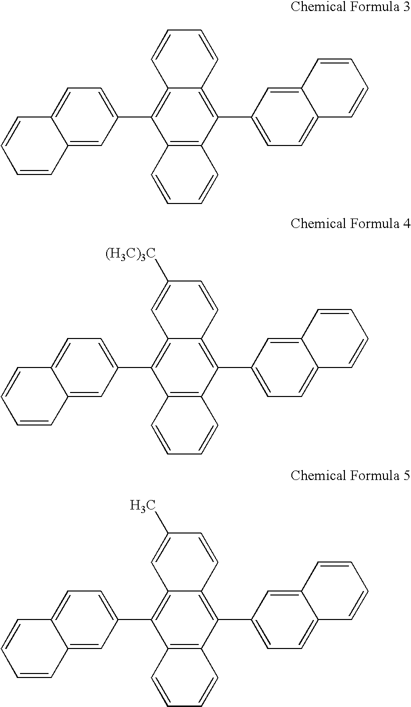

An acene-based material, which generally has a high electron-transportation capability, has a higher electron mobility than an amine-based material. Hence, electrons can be smoothly conveyed from the blue light-emitting layer 8 to the red light-emitting layer 6 through the intermediate layer 7.

The content of the acene-based material in the intermediate layer 7 is preferably, but not limited to, 10% to 90% by weight, more preferably 30% to 70% by weight, and most preferably 40% to 60% by weight.

If the content of the acene-based material in the intermediate layer 7 is A (percent by weight), and the content of the amine-based material in the intermediate layer 7 is B (percent by weight), B/(A+B) is preferably 0.1 to 0.9 more preferably 0.3 to 0.7, and most preferably 0.4 to 0.6. In this case, the intermediate layer 7 more reliably allows light emission by injecting electrons and holes into the red light-emitting layer 6 and the blue light-emitting layer 8 while having a high tolerance to carriers and excitons.

The average thickness of the intermediate layer 7 is preferably, but not limited to, about 1 to 100 nm, more preferably about 3 to 50 nm, and most preferably 5 to 30 nm. In this case, the intermediate layer 7 can prevent energy transfer of excitons between the red light-emitting layer 6 and the blue light-emitting layer 8 more reliably with low drive voltage.

If the average thickness of the intermediate layer 7 exceeds the above upper limit, the drive voltage may be significantly increased, and it may be difficult to achieve the light emission (particularly, white light emission) of the light-emitting device 1, depending on, for example, the materials of the intermediate layer 7. If the average thickness of the intermediate layer 7 falls below the above lower limit, it may be difficult to prevent or inhibit energy transfer of excitons between the red light-emitting layer 6 and the blue light-emitting layer 8, and the intermediate layer 7 tends to have a lower tolerance to carriers and excitons, depending on, for example, the materials of the intermediate layer 7 and the drive voltage.

Blue Light-Emitting Layer

The blue light-emitting layer (second light-emitting layer) 8 contains a blue light-emitting material that emits blue light (second color).

The blue light-emitting material used is not particularly limited. Examples of the blue light-emitting material include various blue fluorescent materials and various blue phosphorescent materials. These materials may be used alone or in combination of two or more.

The blue fluorescent material used may be any material that emits blue fluorescence. Examples of the blue fluorescent material include distyryl derivatives, fluoranthene derivatives, pyrene derivatives, perylene and derivatives thereof, anthracene derivatives, benzoxazole derivatives, benzothiazole derivatives, benzimidazole derivatives, chrysene derivatives, phenanthrene derivatives, distyrylbenzene derivatives, tetraphenylbutadiene, 4,4′-bis(9-ethyl-3-carbazovinylene)-1,1′-biphenyl(BCzVBi), poly[(9,9-dioctylfluorene-2,7-diyl)-co-(2,5-dimethoxybenzene-1,4-diyl)], poly[(9,9-dihexyloxyfluorene-2,7-diyl)-alt-co-(2-methoxy-5-{2-ethoxyhexyloxy}phenylene-1,4-diyl)], and poly[(9,9-dioctylfluorene-2,7-diyl)-co-(ethynylbenzene)]. These materials may be used alone or in combination of two or more.

The blue phosphorescent material used may be any material that emits blue phosphorescence. Examples of the blue phosphorescent material include metal complexes such as those of iridium, ruthenium, platinum, osmium, rhenium, and palladium. Specific examples include bis[4,6-difluorophenylpyridinato-N,C2′]-picolinate-iridium, tris[2-(2,4-difluorophenyl)pyridinato-N,C2′]iridium, bis[2-(3,5-trifluoromethyl)pyridinato-N,C2′]-picolinate-iridium, and bis(4,6-difluorophenylpyridinato-N,C2′)iridium(acetylacetonate).

In addition, like the red light-emitting layer 6, a host material containing the blue light-emitting material as a guest material may be used as the material of the blue light-emitting layer 8.

Green Light-Emitting Layer

The green light-emitting layer (third light-emitting layer) 9 contains a green light-emitting material that emits green light (third color).

The green light-emitting material used is not particularly limited. Examples of the green light-emitting material include various green fluorescent materials and various green phosphorescent materials. These materials may be used alone or in combination of two or more.

The green fluorescent material used may be any material that emits green fluorescence. Examples of the green fluorescent material include coumarin derivatives, quinacridone derivatives, 9,10-bis[(9-ethyl-3-carbazolyl)-vinylenyl]-anthracene, poly(9,9-dihexyl-2,7-vinylenefluorenylene), poly[(9,9-dioctylfluorene-2,7-diyl)-co-(1,4-diphenylene-vinylene-2-methoxy-5-{2-ethylhexyloxy}benzene)], and poly[(9,9-dioctyl-2,7-divinylenefluorenylene)-alt-co-(2-methoxy-5-(2-ethoxyhexyloxy)-1,4-phenylene)]. These materials may be used alone or in combination of two or more.

The green phosphorescent material used may be any material that emits green phosphorescence. Examples of the green phosphorescent material include metal complexes such as those of iridium, ruthenium, platinum, osmium, rhenium, and palladium. In these metal complexes, at least one of their ligands preferably has, for example, a phenylpyridine backbone, a bipyridyl backbone, or a porphyrin backbone. Specific examples include fac-tris(2-phenylpyridine)iridium (Ir(ppy)₃), bis(2-phenylpyridinato-N,C2′)iridium(acetylacetonate), and fac-tris[5-fluoro-2-(5-trifluoromethyl-2-pyridinyl)phenyl-C,N]iridium.

In addition, like the red light-emitting layer 6, a host material containing the green light-emitting material as a guest material may be used as the material of the green light-emitting layer 9.

Electron-Transporting Layer

The electron-transporting layer 10 functions to transport electrons injected from the cathode 12 through the electron-injecting layer 11 to the green light-emitting layer 9.

Examples of the material (electron-transporting material) of the electron-transporting layer 10 include quinoline derivatives (such as organometallic complexes having 8-quinolinol or its derivative as a ligand, for example, tris(8-quinolinolato)aluminum (Alq₃)), oxadiazole derivatives, perylene derivatives, pyridine derivatives, pyrimidine derivatives, quinoxaline derivatives, diphenylquinone derivatives, and nitro-substituted fluorene derivatives. These materials may be used alone or in combination of two or more.

The average thickness of the electron-transporting layer 10 is preferably, but not limited to, about 0.5 to 100 nm, more preferably about 1 to 50 nm.

Electron-Injecting Layer

The electron-injecting layer 11 functions to improve the efficiency of electron injection from the cathode 12.

Examples of the material (electron-injecting material) of the electron-injecting layer 11 include various inorganic insulating materials and various semiconductor materials.

Examples of inorganic insulating materials include alkali metal chalcogenides (oxides, sulfides, selenides, and tellurides), alkaline earth metal chalcogenides, alkali metal halides, and alkaline earth metal halides. These materials may be used alone or in combination of two or more. These materials can be used as the main material of the electron-injecting layer 11 to improve its electron-injection capability. In particular, the light-emitting device 1 can have high luminance if the electron-injecting layer 11 is formed of an alkali metal compound (such as an alkali metal chalcogenide or an alkali metal halide) because it has a very low work function.

Examples of alkali metal chalcogenides include Li₂O, LiO, Na₂S, Na₂Se, and NaO.

Examples of alkaline earth metal chalcogenides include CaO, BaO, SrO, BeO, BaS, MgO, and CaSe.

Examples of alkali metal halides include CsF, LiF, NaF, KF, LiCl, KCl, and NaCl.

Examples of alkaline earth metal halides include CaF₂, BaF₂, SrF₂, MgF₂, and BeF₂.

Examples of inorganic semiconductor materials include oxides, nitrides, and oxynitrides containing at least one element selected from the group consisting of lithium, sodium, barium, calcium, strontium, ytterbium, aluminum, gallium, indium, cadmium, magnesium, silicon, tantalum, antimony, and zinc. These materials may be used alone or in combination of two or more.

The average thickness of the electron-injecting layer 11 is preferably, but not limited to, about 0.1 to 1,000 nm, more preferably about 0.2 to 100 nm, and most preferably about 0.2 to 50 nm.

Sealing Member

The sealing member 13 is disposed so as to cover and hermetically seal the anode 3, the laminate 15, and the cathode 12, thus functioning to block oxygen and water. The sealing member 13 has benefits such as improving the reliability of the light-emitting device 1 and preventing deterioration (improve durability).

Examples of the material of the sealing member 13 include aluminum, gold, chromium, niobium, tantalum, titanium, alloys thereof, silicon oxide, and various resins. If the sealing member 13 is formed of a conductive material, an insulating film, if necessary, is preferably provided between the sealing member 13 and the anode 3, the laminate 15, and the cathode 12 to prevent a short-circuit.

Alternatively, the sealing member 13 may be plate-shaped and disposed opposite the substrate 2, with the gap therebetween sealed using a sealant such as a thermosetting resin.

In the light-emitting device 1 thus configured, the intermediate layer 7, containing the amine-based material and the acene-based material, prevents energy transfer of excitons between the red light-emitting layer 6 and the blue light-emitting layer 8, so that both the red light-emitting layer 6 and the blue light-emitting layer 8 can efficiently emit light. In addition, the intermediate layer 7 allows light emission by injecting electrons and holes into the red light-emitting layer 6 and the blue light-emitting layer 8 while having a high tolerance to electrons and holes because the amine-based material (i.e., a material having an amine backbone) has a hole-transportation capability and the acene-based material (i.e., a material having an acene backbone) has an electron-transportation capability.

In particular, the acene-based material has a high tolerance to excitons and can therefore prevent or inhibit degradation of the intermediate layer 7 due to excitons, thus improving the durability of the light-emitting device 1.

In this embodiment, additionally, the light-emitting device 1 includes, in order from the anode 3 side to the cathode 12 side, the red light-emitting layer 6, the intermediate layer 7, the blue light-emitting layer 8, and the green light-emitting layer 9, so that the device 1 can relatively easily be adapted to emit white light with a good balance between red (R) light, green (G) light, and blue (B) light.

The above light-emitting device 1 can be produced by, for example, the following process.

(1) First, the substrate 2 is prepared, and the anode 3 is formed on the substrate 2.

The anode 3 may be formed by, for example, dry plating such as chemical vapor deposition (CVD) (e.g., plasma-enhanced CVD or thermal CVD) or vacuum deposition; wet plating such as electroplating; spraying; the sol-gel process; metal-organic deposition (MOD); or bonding metal foil.

(2) Next, the hole-injecting layer 4 is formed on the anode 3.

The hole-injecting layer 4 may be formed by, for example, a vapor process based on dry plating such as CVD, vacuum deposition, or sputtering.

The hole-injecting layer 4 may also be formed by, for example, dissolving or dispersing the hole-injecting material in a solvent or dispersing medium, applying the material for forming the hole-injecting layer 4 onto the anode 3, and drying the material (removing the solvent or dispersing medium).

The material for forming the hole-injecting layer 4 may be applied by various coating methods such as spin coating, roll coating, or ink-jet printing. Such coating methods can be used to form the hole-injecting layer 4 relatively easily.

Examples of the solvent or dispersing medium used for the preparation of the material for forming the hole-injecting layer 4 include various inorganic solvents, various organic solvents, and mixed solvents.

The drying may be performed, for example, by leaving the substrate 2 in atmospheric pressure or in a vacuum atmosphere, by heat treatment, or by spraying inert gas.

Before the above step, the top surface of the anode 3 may be subjected to oxygen plasma treatment. This treatment can be performed to make the top surface of the anode 3 lyophilic, to remove (clean) organic matter deposited on the top surface of the anode 3, and to adjust the work function of the top surface of the anode 3.

For example, the oxygen plasma treatment is preferably performed at a plasma power of about 100 to 800 W, an oxygen gas flow rate of about 50 to 100 mL/min, a workpiece (anode 3) transportation speed of about 0.5 to 10 mm/sec, and a substrate temperature of about 70° C. to 90° C.

(3) Next, the hole-transporting layer 5 is formed on the hole-injecting layer 4.

The hole-transporting layer 5 may be formed by, for example, a vapor process based on dry plating such as CVD, vacuum deposition, or sputtering.

The hole-transporting layer 5 may also be formed by, for example, dissolving or dispersing the hole-transporting material in a solvent or dispersing medium, applying the material for forming the hole-transporting layer 5 onto the hole-injecting layer 4, and drying the material (removing the solvent or dispersing medium).

(4) Next, the red light-emitting layer 6 is formed on the hole-transporting layer 5.

The red light-emitting layer 6 may be formed by, for example, a vapor process based on dry plating such as CVD, vacuum deposition, or sputtering.

(5) Next, the intermediate layer 7 is formed on the red light-emitting layer 6.

The intermediate layer 7 may be formed by, for example, a vapor process based on dry plating such as CVD, vacuum deposition, or sputtering.

(6) Next, the blue light-emitting layer 8 is formed on the intermediate layer 7.

The blue light-emitting layer 8 may be formed by, for example, a vapor process based on dry plating such as CVD, vacuum deposition, or sputtering.

(7) Next, the green light-emitting layer 9 is formed on the blue light-emitting layer 8.

The green light-emitting layer 9 may be formed by, for example, a vapor process based on dry plating such as CVD, vacuum deposition, or sputtering.

(8) Next, the electron-transporting layer 10 is formed on the green light-emitting layer 9.

The electron-transporting layer 10 may be formed by, for example, a vapor process based on dry plating such as CVD, vacuum deposition, or sputtering.

The electron-transporting layer 10 may also be formed by, for example, dissolving or dispersing the electron-transporting material in a solvent or dispersing medium, applying the material for forming the electron-transporting layer 10 onto the green light-emitting layer 9, and drying the material (removing the solvent or dispersing medium).

(9) Next, the electron-injecting layer 11 is formed on the electron-transporting layer 10.

If the electron-injecting layer 11 is formed of an inorganic material, it may be formed by, for example, a vapor process based on dry plating such as CVD, vacuum deposition, or sputtering, or by applying and firing an inorganic microparticle ink.

(10) Next, the cathode 12 is formed on the electron-injecting layer 11.

The cathode 12 may be formed by, for example, vacuum deposition, sputtering, bonding metal foil, or applying and firing a metal microparticle ink.

Thus, the light-emitting device 1 can be produced by the above process.

Finally, the sealing member 13 is placed on and bonded to the substrate 2 so as to cover the light-emitting device 1.

### Second Embodiment

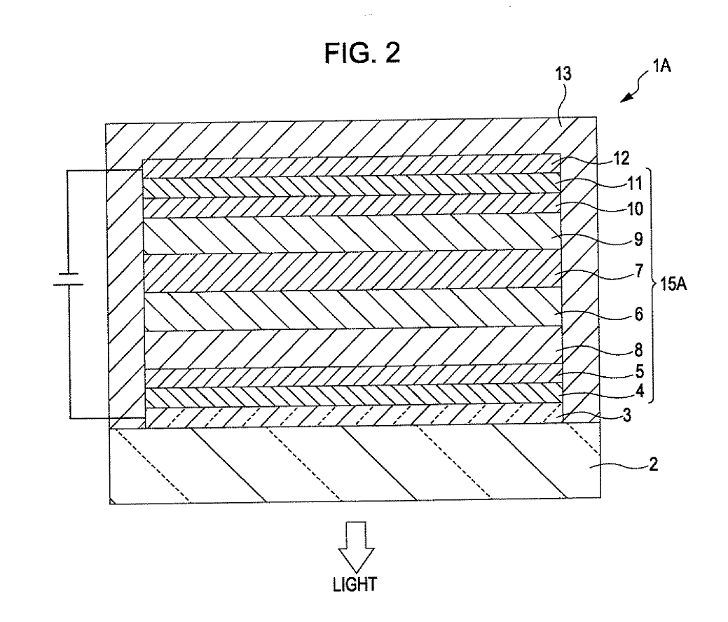

FIG. 2 is a longitudinal sectional view schematically showing a light-emitting device according to a second embodiment of the invention. For convenience of illustration, the top of FIG. 2 is referred to as the “top” of the device, whereas the bottom of FIG. 2 is referred to as the “bottom” of the device.

A light-emitting device 1A according to this embodiment is the same as the light-emitting device 1 according to the first embodiment except that the light-emitting layers 6, 8, and 9 and the intermediate layer 7 are stacked in a different order.

Referring to FIG. 2, the anode 3, the hole-injecting layer 4, the hole-transporting layer 5, the blue light-emitting layer (third light-emitting layer) 8, the red light-emitting layer (first light-emitting layer) 6, the intermediate layer 7, the green light-emitting layer (second light-emitting layer) 9, the electron-transporting layer 10, the electron-injecting layer 11, and the cathode 12 are stacked on the substrate 2 in the above order and are sealed by the sealing member 13.

In other words, the light-emitting device 1A includes a laminate 15A formed between the anode 3 and the cathode 12 by stacking the hole-injecting layer 4, the hole-transporting layer 5, the blue light-emitting layer 8, the red light-emitting layer 6, the intermediate layer 7, the green light-emitting layer 9, the electron-transporting layer 10, and the electron-injecting layer 11 in the above order from the anode 3 side to the cathode 12 side. The light-emitting device 1A is disposed on the substrate 2 and is sealed by the sealing member 13.

The light-emitting device 1A thus configured has the same advantages as the light-emitting device 1 according to the first embodiment.

In this embodiment, particularly, the light-emitting device 1A includes, in order from the anode 3 side to the cathode 12 side, the blue light-emitting layer 8, the red light-emitting layer 6, the intermediate layer 7, and the green light-emitting layer 9, so that the device 1A can relatively easily be adapted to emit white light with a good balance between red (R) light, green (G) light, and blue (B) light.

The light-emitting device 1 and the light-emitting device 1A described above may be used as, for example, light sources. In addition, a plurality of light-emitting devices 1 or light-emitting devices 1A may be arranged in a matrix to constitute a display.

The display-driving system used is not particularly limited and may be either an active-matrix system or a passive-matrix system.

Next, an example of a display according to an embodiment of the invention will be described.

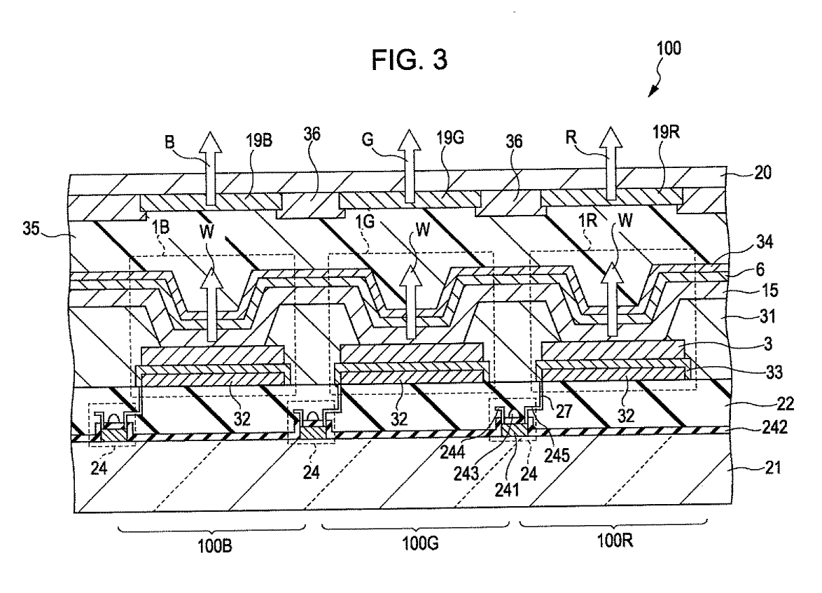

FIG. 3 is a longitudinal sectional view showing the display according to this embodiment.

Referring to FIG. 3, a display 100 includes a substrate 21, light-emitting devices 1R, 1G, and 1B and color filters 19R, 19G, and 19B corresponding to subpixels 100R, 100G, and 100B, respectively, and drive transistors 24 for driving the light-emitting devices 1R, 1G, and 1B. The display 100 is a top-emission display panel.

The drive transistors 24 are disposed on the substrate 21. A planarizing layer 22 is disposed over the drive transistors 24. The planarizing layer 22 is formed of an insulating material.

The drive transistors 24 each include a semiconductor layer 241 formed of silicon, a gap insulating layer 242 on the semiconductor layer 241, a gate electrode 243 on the gap insulating layer 242, a source electrode 244, and a drain electrode 245.

The light-emitting devices 1R, 1G, and 1B are disposed on the planarizing layer 22, corresponding to the individual drive transistors 24.

The light-emitting devices 1R each include a reflective film 32, an anticorrosive film 33, an anode 3, a laminate (organic EL portion) 15, a cathode 6, and a cathode cover 34 that are stacked on the planarizing layer 22 in the above order. In this embodiment, the anodes 3 of the light-emitting devices 1R, 1G, and 1B constitute pixel electrodes and are electrically connected to the drain electrodes 245 of the drive transistors 24 via conductors (wiring lines) 27. The cathode 6 of the light-emitting devices 1R, 1G, and 1B constitutes a common electrode.

The light-emitting devices 1G and 1B have the same structure as the light-emitting devices 1R. The structure (properties) of the reflective film 32 may be different between the light-emitting devices 1R, 1G, and 1B depending on the wavelength of light.

A partition 31 is disposed between the adjacent light-emitting devices 1R, 1G, and 1B, and an epoxy layer 35 formed of epoxy resin is disposed over the light-emitting devices 1R, 1G, and 1B.

The color filters 19R, 19G, and 19B are disposed on the epoxy layer 35, corresponding to the light-emitting devices 1R, 1G, and 1B, respectively.

The color filters 19R convert white light W from the light-emitting devices 1R into red light. The color filters 19G convert white light W from the light-emitting devices 1G into green light. The color filters 19B convert white light W from the light-emitting devices 1B into blue light. The light-emitting devices 1R, 1G, and 1B can thus be used in combination with the color filters 19R, 19G, and 19B to display a full-color image.

A light-shielding layer 36 is disposed between the adjacent color filters 19R, 19G, and 19B. This light-shielding layer 36 can block unwanted light from the subpixels 100R, 100G, and 100B.

A sealing substrate 20 is disposed over the color filters 19R, 19G, and 19B and the light-shielding layer 36.

The above display 100 may be configured as a monochrome display or as a color display using selected materials for the light-emitting devices 1R, 1G, and 1B.

The display 100 can be incorporated in various electronic apparatuses.

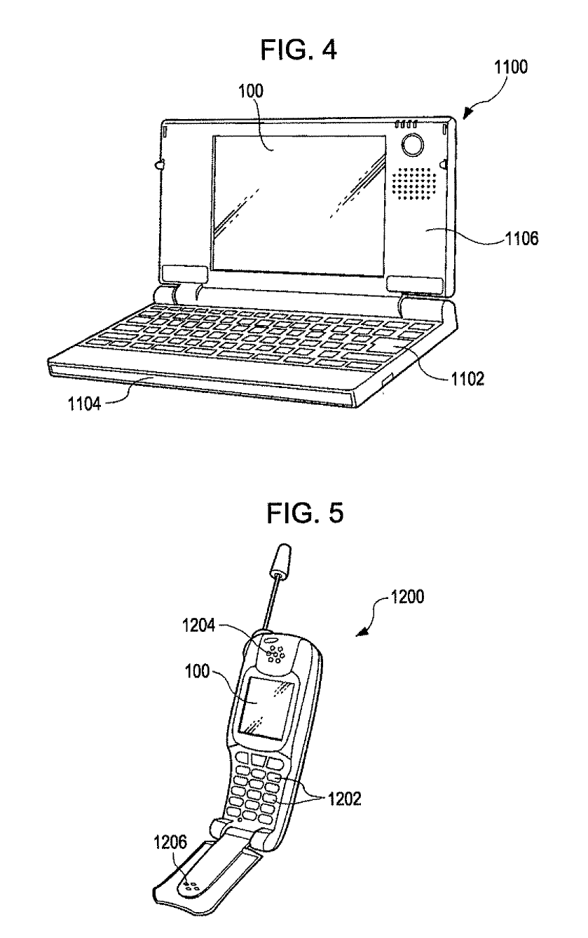

FIG. 4 is a perspective view showing a mobile (notebook) personal computer as an example of an electronic apparatus according to an embodiment of the invention.

In FIG. 4, a personal computer 1100 includes a main body 1104 having a keyboard 1102 and a display unit 1106 having a display section. The display unit 1106 is supported so as to be rotatable relative to the main body 1104 about a hinge.

In the personal computer 1100, the display section of the display unit 1106 includes the display 100 described above.

FIG. 5 is a perspective view showing a cellular phone (or PHS) as an example of an electronic apparatus according to another embodiment of the invention.

In FIG. 5, a cellular phone 1200 includes a plurality of operating buttons 1202, an earpiece 1204, a mouthpiece 1206, and a display section.

In the cellular phone 1200, the display section includes the display 100 described above.

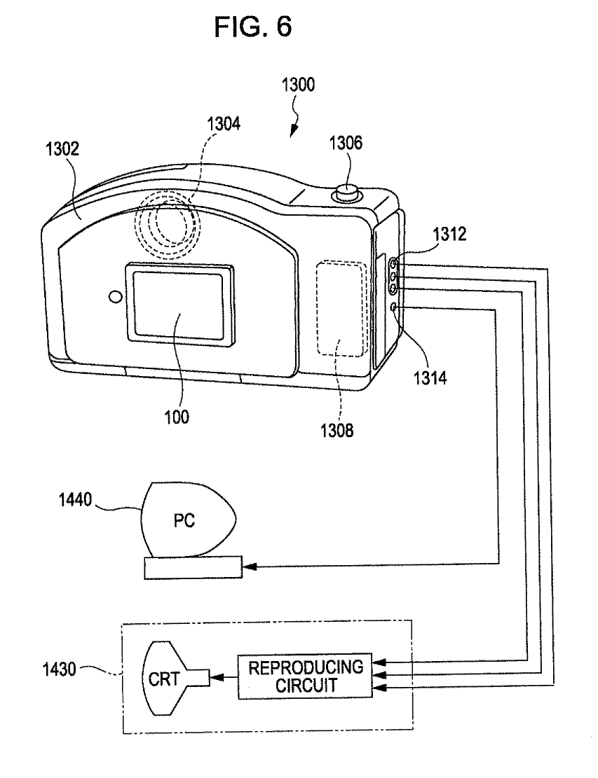

FIG. 6 is a perspective view showing a digital still camera as an example of an electronic apparatus according to another embodiment of the invention, where connections to external devices are also briefly shown.

While a normal camera exposes a silver-salt photographic film to an optical image of a subject, a digital still camera 1300 photoelectrically converts an optical image of a subject into imaging signals (image signals) through an imaging device such as a charge-coupled device (CCD).

The digital still camera 1300 includes a display section on the rear of a case (body) 1302 to display an image based on the imaging signals generated by the imaging device. That is, the display section functions as a viewfinder for displaying an electronic image of the subject.

In the digital still camera 1300, the display section includes the display 100 described above.

The case 1302 incorporates a circuit board 1308 on which a memory is mounted to store the imaging signals.

The digital still camera 1300 also includes a light-receiving unit 1304 on the front of the case 1302 (on the backside in FIG. 6). The light-receiving unit 1304 includes, for example, an optical lens (imaging optical system) and the imaging device.

When the user presses a shutter button 1306 while seeing a subject image displayed on the display section, the imaging signals of the imaging device at that time are transmitted to and stored in the memory on the circuit board 1308.

The digital still camera 1300 also has video-signal output terminals 1312 and a data-communication input/output terminal 1314 on the side of the case 1306. The video-signal output terminals 1312 are optionally connected to a monitor 1430, whereas the data-communication input/output terminal 1314 is optionally connected to a personal computer 1440. With a predetermined manipulation, the imaging signals can be fed from the memory on the circuit board 1308 to the monitor 1430 and the personal computer 1440.

In addition to the personal computer of FIG. 4 (mobile personal computer), the cellular phone of FIG. 5, and the digital still camera of FIG. 6, examples of electronic apparatuses according to embodiments of the invention include television sets, viewfinder- or monitor-equipped camcorders, laptop personal computers, car navigation systems, pagers, electronic organizers (with or without communications capabilities), electronic dictionaries, calculators, electronic game machines, word processors, work stations, video phones, security monitors, electronic binoculars, POS terminals, touch panel-equipped devices (such as cash dispensers of financial institutions or automatic ticket machines), medical equipment (such as electronic thermometers, sphygmomanometers, blood glucose meters, electrocardiograph displays, medical ultrasound equipment, and endoscope displays), fish finders, a variety of measurement equipment, a variety of instruments (such as those used for cars, aircrafts, and ships), flight simulators, various other monitors, and projection displays such as projectors.

The light-emitting devices, displays, and electronic apparatuses according to the embodiments shown in the drawings have been described above, although the invention is not limited thereto.

The light-emitting devices according to the above embodiments, for example, include three light-emitting layers, although they may include two or four or more light-emitting layers. In addition, the colors of light of the light-emitting layers are not limited to the three colors used in the above embodiment, namely, red, green, and blue; two or four or more light-emitting layers can be used to emit white light by adjusting the emission spectra of the light-emitting layers.

Furthermore, an intermediate layer may be provided in at least one of the interfaces between the light-emitting layers, and two or more intermediate layers may be provided.

### EXAMPLES

Next, examples of the invention will be described.

1. Production of Light-Emitting Device

### Example 1

(1) First, a transparent glass substrate with an average thickness of 0.5 mm was prepared. An ITO electrode (anode) with an average thickness of 100 nm was formed on the substrate by sputtering.

The substrate was dipped in acetone and then in 2-propanol and was subjected to ultrasonic cleaning before the substrate was subjected to oxygen plasma treatment.

(2) Next, a hole-injecting layer with an average thickness of 40 nm was formed on the ITO electrode by vacuum deposition using HI406 (manufactured by Idemitsu Kosan Co., Ltd.).

(3) Next, a hole-transporting layer with an average thickness of 20 nm was formed on the hole-injecting layer by vacuum deposition using HT320 (manufactured by Idemitsu Kosan Co., Ltd.).

(4) Next, a red light-emitting layer (first light-emitting layer) with an average thickness of 10 nm was formed on the hole-transporting layer by vacuum deposition using the material of the red light-emitting layer. The material of the red light-emitting layer contained RD001 (manufactured by Idemitsu Kosan Co., Ltd.) as a red light-emitting material (guest material) and rubrene as a host material. The content (dosage) of the red light-emitting material (dopant) in the red light-emitting layer was 1.0% by weight.

(5) Next, an intermediate layer with an average thickness of 7 nm was formed on the red light-emitting layer by vacuum deposition using the material of the intermediate layer. The material of the intermediate layer contained α-NPD, represented by Chemical Formula 1 above, as the amine-based material and ADN, represented by Chemical Formula 3 above, as the acene-based material. The content of the amine-based material in the intermediate layer was 50% by weight, whereas the content of the acene-based material in the intermediate layer was 50% by weight.

(6) Next, a blue light-emitting layer (second light-emitting layer) with an average thickness of 15 nm was formed on the intermediate layer by vacuum deposition using the material of the blue light-emitting layer. The material of the blue light-emitting layer contained BD102 (manufactured by Idemitsu Kosan Co., Ltd.) as a blue light-emitting material (guest material) and BH215 (manufactured by Idemitsu Kosan Co., Ltd.) as a host material. The content (dosage) of the blue light-emitting material (dopant) in the blue light-emitting layer was 5.0% by weight.

(7) Next, a green light-emitting layer (third light-emitting layer) with an average thickness of 25 nm was formed on the blue light-emitting layer by vacuum deposition using the material of the green light-emitting layer. The material of the green light-emitting layer contained GD206 (manufactured by Idemitsu Kosan Co., Ltd.) as a green light-emitting material (guest material) and BH215 (manufactured by Idemitsu Kosan Co., Ltd.) as a host material. The content (dosage) of the green light-emitting material (dopant) in the green light-emitting layer was 8.0% by weight.

(8) Next, an electron-transporting layer with an average thickness of 20 nm was formed on the green light-emitting layer by vacuum deposition using tris(8-quinolinolato)aluminum (Alq₃).

(9) Next, an electron-injecting layer with an average thickness of 0.5 nm was formed on the electron-transporting layer by vacuum deposition using lithium fluoride (LiF).

(10) Next, a cathode with an average thickness of 150 nm was formed on the electron-injecting layer by vacuum deposition using aluminum.

(11) Next, a glass protective cover (sealing member) was placed over the layers and was bonded and sealed with epoxy resin.

Light-emitting devices as shown in FIG. 1 were thus produced by the above process.

### Example 2

Light-emitting devices were produced in the same manner as in Example 1 expect that the intermediate layer was formed using TBADN, represented by Chemical Formula 4 above, as the acene-based material.

### Example 3

Light-emitting devices were produced in the same manner as in Example 1 expect that the intermediate layer was formed using MADN, represented by Chemical Formula 5 above, as the acene-based material.

### Example 4

Light-emitting devices were produced in the same manner as in Example 1 expect that the intermediate layer was formed using TNB represented by Chemical Formula 2 above, as the amine-based material.

### Example 5

Light-emitting devices were produced in the same manner as in Example 1 expect that the intermediate layer had an average thickness of 15 nm.

### Example 6

Light-emitting devices were produced in the same manner as in Example 1 expect that the intermediate layer had an average thickness of 20 nm.

### Example 7

Light-emitting devices were produced in the same manner as in Example 1 expect that the anode, the hole-injecting layer, the hole-transporting layer, the blue light-emitting layer, the red light-emitting layer, the intermediate layer, the green light-emitting layer, the electron-transporting layer, the electron-injecting layer, and the cathode were formed on the substrate in the above order and that the thicknesses of the blue light-emitting layer, the red light-emitting layer, and the intermediate layer and the dosage of the blue light-emitting material in the blue light-emitting layer were changed. Thus, light-emitting devices as shown in FIG. 2 were produced.

The blue light-emitting layer had an average thickness of 15 nm. The red light-emitting layer had an average thickness of 5 nm. The intermediate layer had an average thickness of 10 nm. The dosage of the blue light-emitting material in the blue light-emitting layer was 8% by weight.

### Comparative Example 1

Light-emitting devices were produced in the same manner as in Example 1 expect that the intermediate layer was formed without using ADN but only of α-NPD.

### Comparative Example 2

Light-emitting devices were produced in the same manner as in Example 7 expect that the intermediate layer was formed without using ADN but only of α-NPD.

2. Evaluation

2-1. Evaluation of Light-Emission Efficiency

The light-emitting devices of the examples of the invention and the comparative examples were supplied with a constant current of 100 mA/cm² from a DC power supply, and their luminances (initial luminances) were measured using a luminance meter. For each of the examples of the invention and the comparative examples, the measurement was performed on five light-emitting devices.

Table 1 shows the measured luminances of Examples 1 to 7, where the luminances of Examples 1 to 6 are represented with respect to that of Comparative Example 1, and the luminance of Example 7 is represented with respect to that of Comparative Example 2.

TABLE 1

| | Chromaticity | | | Light-emission |
|---|---|---|---|---|
| | x | y | Lifetime (LT80) | efficiency |
| Example 1 | 0.42 | 0.38 | 4.2 | 0.75 |
| Example 2 | 0.42 | 0.37 | 4.5 | 0.71 |
| Example 3 | 0.42 | 0.38 | 4.2 | 0.75 |
| Example 4 | 0.42 | 0.38 | 4.0 | 0.72 |
| Example 5 | 0.42 | 0.38 | 4.8 | 0.70 |
| Example 6 | 0.42 | 0.38 | 5.1 | 0.71 |
| Comparative | 0.34 | 0.42 | 1.0 | 1.0 |
| Example 1 | | | | |
| Example 7 | 0.34 | 0.46 | 3.4 | 0.88 |
| Comparative | 0.38 | 0.46 | 1.0 | 1.0 |
| Example 2 | | | | |

2-2. Evaluation of Light-Emission Lifetime

The light-emitting devices of the examples of the invention and the comparative examples continued to be supplied with a constant current of 100 mA/cm² from a DC power supply while their luminances were measured using a luminance meter to measure the time (LT80) at which the luminances decreased to 80% of the initial luminances. For each of the examples of the invention and the comparative examples, the measurement was performed on five light-emitting devices.

Table 1 shows the measured times (LT80) of Examples 1 to 7, where the measured times (LT80) of Examples 1 to 6 are represented with respect to that of Comparative Example 1, and the measured time (LT80) of Example 7 is represented with respect to that of Comparative Example 2.

2-3. Evaluation of Chromaticity

The light-emitting devices of the examples of the invention and the comparative examples were supplied with a constant current of 100 mA/cm² from a DC power supply, and their chromaticities (x,y) were measured using a chromaticity meter.

Table 1 shows that the light-emitting devices of the examples of the invention showed superior durability while their chromaticity balances and light-emission efficiencies were comparable to those of the light-emitting devices of the comparative examples for reference.

What is claimed is:

1. A light-emitting device comprising:
a cathode;
an anode;
a first light-emitting layer that is disposed between the cathode and the anode and that emits light of a first color;
a second light-emitting layer that is disposed between the first light-emitting layer and the cathode and that emits light of a second color different from the first color; and
an intermediate layer that is disposed between and in contact with the first light-emitting layer and the second light-emitting layer and that functions to prevent energy transfer of excitons between the first light-emitting layer and the second light-emitting layer, the intermediate layer containing an acene-based material and an amine-based material.

2. The light-emitting device according to claim 1, wherein the acene-based material has a higher electron mobility than the amine-based material.

3. The light-emitting device according to claim 1, wherein the amine-based material has a higher hole mobility than the acene-based material.

4. The light-emitting device according to claim 1, wherein the acene-based material is an anthracene derivative.

5. The light-emitting device according to claim 4, wherein the anthracene derivative has naphthyl groups at the 9- and 10-positions of an anthracene backbone.

6. The light-emitting device according to claim 1, wherein the intermediate layer has an average thickness of 1 to 100 nm.

7. The light-emitting device according to claim 1, wherein if the content of the acene-based material in the intermediate layer is A (percent by weight), and the content of the amine-based material in the intermediate layer is B (percent by weight), B/(A+B) is 0.1 to 0.9.

8. The light-emitting device according to claim 1, further comprising a third light-emitting layer that is disposed between the first light-emitting layer and the anode or between the second light-emitting layer and the cathode and that emits light of a third color different from the first and second colors.

9. The light-emitting device according to claim 8, wherein the first light-emitting layer is a red light-emitting layer that emits red light as the light of the first color.

10. The light-emitting device according to claim 9, wherein
the third light-emitting layer is a green light-emitting layer that is disposed between the second light-emitting layer and the cathode and that emits green light as the light of the third color; and
the second light-emitting layer is a blue light-emitting layer that emits blue light as the light of the second color.

11. The light-emitting device according to claim 9, wherein
the third light-emitting layer is a blue light-emitting layer that is disposed between the first light-emitting layer and the anode and that emits blue light as the light of the third color; and
the second light-emitting layer is a green light-emitting layer that emits green light as the light of the second color.

12. A display comprising the light-emitting device according to claim 1.

13. An electronic apparatus comprising the display according to claim 12.
